(19) United States
(12) Patent Application Publication
(10) Pub. No.: US 2006/0054311 A1
(43) Pub. Date: Mar. 16, 2006

(54) Heat sink device with independent parts

(76) Inventors: Andrew Douglas Delano, Fort Collins, CO (US); Bradley Edgar Clements, Fort Collins, CO (US)

Correspondence Address: HEWLETT-PACKARD COMPANY;Intellectual Property Administration, P.O. Box 272400, Fort Collins, CO, 80527-2400, US

(21) Appl. No.: 10/941,157

(22) Filed: Sep. 15, 2004

(51) Int. Cl. H01L 23/467

(52) U.S. Cl. 165/121

(57) ABSTRACT

Systems, methodologies, and other embodiments associated with a heat sink with independent parts are described. An example heat sink apparatus may be configured to house a fan that is configured to produce a dual air flow in the heat sink apparatus. An example heat sink may include a base and separately manufactured fins.

### BACKGROUND

Heat sink devices like fan-assisted dual air flow heat sinks have typically been manufactured from a single thermally conductive material. Furthermore, heat sink devices have also typically had their fins and base manufactured from the same blank or poured into the same mold. By way of illustration, a single extruded solid round bar of aluminum may be machined with a lathe, a circular slitting saw, and the like, to form the base and fins for a heat sink device into which a fan may be fitted to produce a dual air flow. Similarly, copper may be molded into an integrated base with fins. Producing these devices from a single blank or in a single mold may introduce certain limitations into these heat sink devices.

An example conventional fan-assisted dual air flow heat sink cooling device is described in U.S. Pat. No. 5,785,116, issued Jul. 28, 1998. The '116 patent describes a heat sink having a housing that is constructed from a plurality of cooling vanes over which air passes twice. However, the '116 patent describes the heat sink assembly as being integrally formed to prevent heat conductance losses ordinarily associated with joints.

### BRIEF DESCRIPTION OF THE DRAWINGS

The accompanying drawings, which are incorporated in and constitute a part of the specification, illustrate various embodiments of aspects of the invention. It will be appreciated that the illustrated element boundaries (e.g., boxes, groups of boxes, or other shapes) in the figures represent one example of the boundaries. One of ordinary skill in the art will appreciate that one element may be designed as multiple elements or that multiple elements may be designed as one element. An element shown as an internal component of another element may be implemented as an external component and vice versa. Furthermore, elements may not be drawn to scale.

FIG. 1 illustrates an example embodiment of a heat sink device configured to experience a fan-assisted dual air flow.

FIG. 2 illustrates an example embodiment of a base for a heat sink device configured to experience a fan-assisted dual air flow.

FIG. 3 illustrates an example embodiment of a fin for a heat sink device configured to experience a fan-assisted dual air flow.

FIG. 4 illustrates an example embodiment of a base for a heat sink device configured to experience a fan-assisted dual air flow and an example independently manufactured fin attached to the base.

FIG. 5 illustrates an example embodiment of a base for a heat sink device configured to experience a fan-assisted dual air flow and a plurality of independently manufactured fins attached to the base.

FIG. 6 illustrates an example embodiment of a base with a plurality of fins attached and a cavity in which a fan may be housed.

FIG. 7 illustrates an example embodiment of an independently manufactured fin for a heat sink device configured to experience a fan-assisted dual air flow, the example fin being configured with finlets.

FIG. 8 illustrates another example embodiment of an independently manufactured fin for a heat sink device configured to experience a fan-assisted dual air flow, the example fin being configured with various features to affect air flow.

FIG. 9 illustrates another example embodiment of an independently manufactured fin for a heat sink device configured to experience a fan-assisted dual air flow, the example fin being configured with raised features designed to mitigate a boundary layer effect produced by air flowing over the fin.

FIG. 10 illustrates an example method for removing heat from a heat source using a heat sink device configured to experience a fan-assisted dual air flow, where the heat sink device is assembled from independently manufactured parts.

FIG. 11 illustrates an example embodiment of a fin having an increasing cross-sectional area with respect to radius and a channel having a constant cross-sectional area with respect to radius.

FIG. 12 illustrates example embodiment of fins having a constant cross-sectional area with respect to radius and a channel having an increasing cross-sectional area with respect to radius.

FIG. 13 illustrates an example method associated with assembling a heat sink from independent parts.

### DETAILED DESCRIPTION

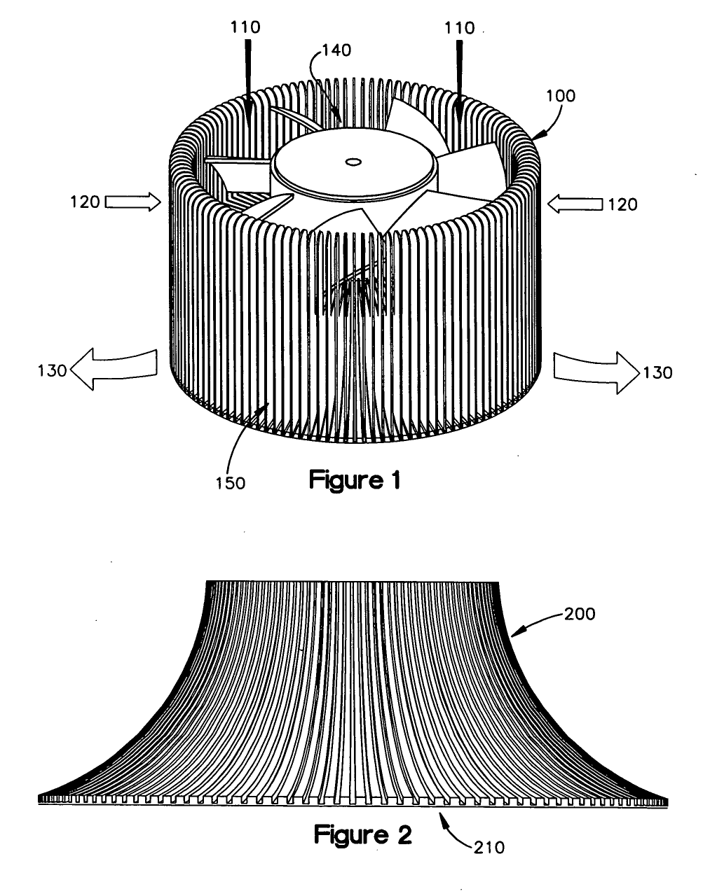

FIG. 1 illustrates an example heat sink device 100 that is configured to experience a fan-assisted dual air flow. Because a fan housing for the heat sink device 100 is constructed from a set of fins 150, air is caused to enter the housing through the housing wall as well as from an open top of the housing. Also, air being exhausted from the heat sink device 100 is caused to pass over the fins 150 a second time. Thus a dual air flow is produced. A first flow 110-130 is produced by fan 140 drawing air into the heat sink device 100 and expelling the air at 130. As the air is expelled at 130, it passes through channels between fins 150. Thus, heat conducted from a heat source into the fins 150 may be dissipated by convection into air flow 110-130. A second flow 120-130 is produced as a result of flow 110-130 in the heat sink 100. Flow 110-130 may produce a Bernoulli effect inside heat sink 100 whereby a relatively lower pressure area is produced inside heat sink 100. Thus, flow 120-130 may result as air from the relatively higher pressure area outside heat sink 100 is drawn into the relatively lower pressure area inside the heat sink 100. Air in flow 120-130 also passes through channels between fins 150, facilitating additional convective cooling and thus producing the second flow in a dual air flow heat sink.

Conventionally, heat sink 100 may have been machined from a solid piece of a suitable thermally conductive and machinable material. For example, an extruded bar of aluminum may have been machined using a lathe, a circular slitting saw, and the like. When the fins and base of a heat sink are manufactured from this single solid piece of material, the shape of a channel between any two fins may be limited to, for example, a straight or circular shape, as determined by the device cutting the channel. Similarly, the depth of the channel may be limited by the device cutting the channel. These manufacturing constraints may lead to fins with suboptimal shapes with respect to conduction and/or convection. For example, as illustrated in FIG. 11, fins 1100 may have an increasing cross sectional area with respect to radius while channel 1110 may have a constant cross sectional area with respect to radius. Other fin and channel shapes like fins 1200 illustrated in FIG. 12 may be more conducive to heat conduction on an extended surface. Additionally, it may be difficult, if possible at all, to introduce an additional shape onto a fin. Thus fins may be relatively smooth, which may lead to a boundary layer insulative effect being produced as air moves over fins 150. Since fins 150 are supposed to facilitate heat dissipation, any insulating boundary layer effect is counterproductive to the function of a heat sink.

Additionally, manufacturing the fins and base of a heat sink from a single solid piece of material limits the fins and base to being made from the same material. For example, both the fins and base may be copper or both the fins and base may be aluminum. But conventionally, the fins may not be aluminum and the base copper. Certain applications (e.g., rack mounted systems, aeronautic applications), and certain considerations (e.g., vibration, worker safety, system safety), may introduce weight and/or heat dissipation requirements that may call for manufacturing a heat sink with its base and fins having different thermally conductive materials.

FIG. 2 illustrates an example base 200 for a heat sink device. Base 200 may be manufactured separately from fins that will be attached to it. Base 200 may have, for example, a hyperboloid shape. In one example, base 200 may be employed in a heat sink device configured to experience a fan-assisted dual air flow. While a hyperboloid shaped base 200 is illustrated, it is to be appreciated that bases with other shapes including other hyperbolic shapes may be employed with independently manufactured fins to produce a heat sink device having a fan-assisted dual air flow.

Since base 200 is manufactured independently from fins that may be attached to base 200, features may be manufactured into base 200 that may facilitate, for example, form fitting base 200 to a heat source and/or attaching different types of fins to base 200. In one example, base 200 may include a contacting surface 210 (e.g., the bottom of base 200) that may be machined, forged, or so on, to facilitate attaching base 200 to a heat source. By way of illustration, contacting surface 210 may be machined to include a cavity for receiving the top of a heat source. Thus, thermal contact between base 200 and the heat source may be improved. By way of further illustration, contacting surface 210 may be manufactured to include rails that facilitate sliding base 200 onto a heat source and holding base 200 in place on the heat source. While machining a cavity and rails into contacting surface 210 are described, it is to be appreciated that other features may be manufactured into base 200 that are difficult, if possible at all, to produce when base 200 and its fins are made as an integral unit from a single block of material.

Since base 200 is manufactured separately from attachable fins, base 200 may be made from the same or a different material than the attachable fins. For example, a first base may be manufactured from a first thermally conductive material like copper, aluminum, gold, silver, combinations of materials and compositions thereof. Fins that may be attached to base 200 may then be manufactured from a second thermally conductive material like aluminum, copper, and so on. Thus, various combinations of base and fins (e.g., Cu/AL, Cu/Cu, Al/Cu, Al/Al) may be produced to meet desired heat sink properties including, but not limited to, heat dissipation, weight, vibration control, and so on. While copper and aluminum are described, it is to be appreciated that base 200 and/or fins may be made from other suitable thermally conductive materials. Example conductive materials may include graphite, carbon, gold, silver, combinations of materials, and/or compositions based on the example materials like graphite/carbon fibers and others.

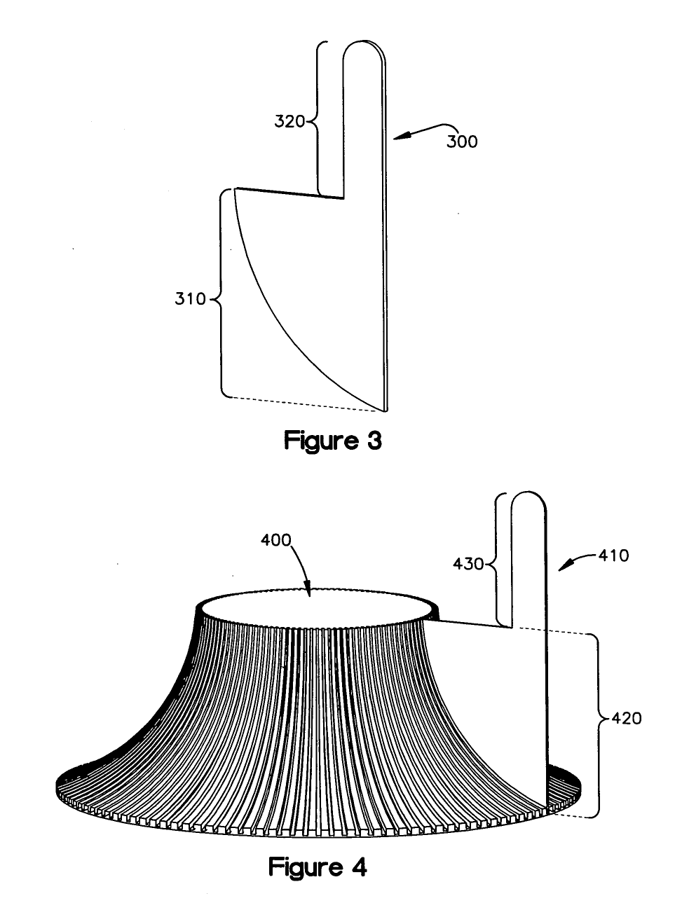

FIG. 3 illustrates an example fin 300. Fin 300 may be manufactured independently from a base to which it may be attached later. In one example, fin 300 may be employed in a heat sink device configured to experience a fan-assisted dual air flow. Fin 300 may include, for example, a first portion 310 configured to be attached to a base and that may experience a first air flow in a heat sink device configured to experience a fan-assisted dual air flow. Additionally, fin 300 may include a second portion 320 that may experience a second air flow in a heat sink device configured to experience a fan-assisted dual air flow. While FIG. 3 illustrates a fin 300 having a first shape, it is to be appreciated that fins with different shapes may be produced independently and attached to various bases. Also, while portion 310 is described as experiencing the first air flow and portion 320 is described as experiencing the second air flow, it is to be appreciated that different fins with different shapes may experience different air flows in different areas. As described above in connection with FIG. 2, since fin 300 is manufactured separately from a base to which fin 300 may be attached, fin 300 may be made from one thermally conductive material while the base to which it is attached may be made from the same or a different thermally conductive material.

FIG. 4 illustrates an example base 400 to which a fin 410 has been attached. Base 400 may be manufactured separately from fin 410 and may be, for example, a hyperboloid shape. The base 400 and fin 410 may be employed, for example, in a heat sink device configured to experience a fan-assisted dual air flow. Fin 410 may be attached to base 400 using methods including, but not limited to, welding, soldering, male/female attachments, and so on. While fin 410 is illustrated being attached to base 400, it is to be appreciated that fin 410 could be attached to other bases having other shapes and being manufactured from other thermally conductive materials. Over time, heat dissipation requirements for a heat source may change, a fin may become damaged, and so on. Thus, in one example, fin 410 and/or other fins attached to base 400 may be removed and replaced with other fins. Fin 410 may include a first portion 420 that is configured to experience a first air flow as, for example, air is exhausted from base 400. Fin 410 may also include a second portion 430 that is configured to experience a second air flow as, for example, air is drawn into a heat sink device by a Bernoulli effect.

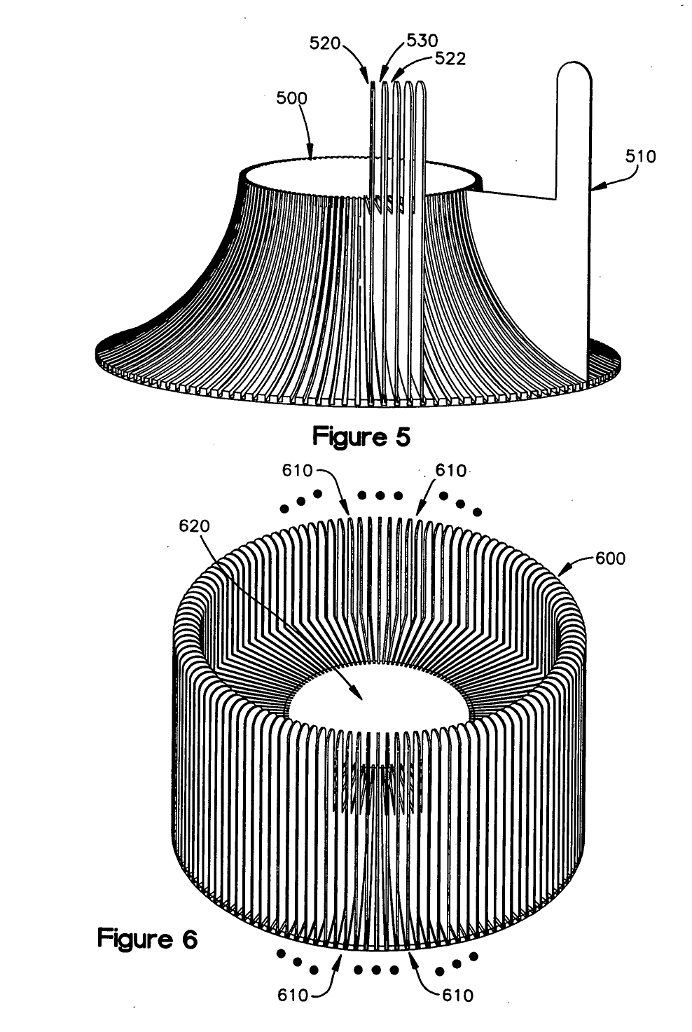

FIG. 5 illustrates an example base 500 to which a fin 510 and fins 520 and 522 have been attached. Base 500 may be manufactured separately from fins 510, 520 and 522 and may be, for example, a hyperboloid shape. The base 500, and fins 510, 520, and 522 may be employed, for example, in a heat sink device having a fan-assisted dual air flow. A channel 530 may be formed between fins 520 and 522. As described above, channels in conventional heat sinks manufactured from a single block of material may have been limited with respect to size, shape, depth, and so on. Since fins 520 and 522 may be manufactured separately and then attached to base 500, the size, shape, depth, and so on of channels between fins 520 and 522 is not so limited.

For example, as illustrated in FIG. 12, a channel 1210 that has increasing cross-sectional area with respect to radius may be produced by manufacturing and attaching fins 1200 that have a constant cross-sectional area with respect to radius. This may facilitate improving heat dissipation properties associated with heat conduction on an extended surface. Fins 520 and 522 are illustrated as being substantially similar to each other. However, it is to be appreciated that since fins 520 and 522 are manufactured separately from base 500, that fins 520 and 522 need not be substantially similar to each other. In one example, a first fin may have a first set of properties (e.g., size, shape, material) while a second fin may have a second set of properties (e.g., size, shape, material). Sets of first and second fins may be arranged in patterns on base 500 to create channels with desired properties (e.g., size, shape, orientation).

FIG. 6 illustrates an example assembly 600 of a base and fins after a plurality of fins 610 have been attached to the base. The base in assembly 600 may be manufactured separately from fins 610 and may have, for example, a hyperboloid shape. Assembly 600 of a base and fins 610 may produce a cavity 620 in which a fan may be housed to facilitate producing a heat sink assembly configured to experience a fan-assisted dual air flow. FIG. 6 illustrates a substantially complete set of fins 610 being attached to a base. In conventional heat sinks, the number of fins that can be attached to a base may be fixed and limited by the machine tools, forging method, and so on employed to create a heat sink. By independently manufacturing a base and fins 610, and then attaching the fins 610 to the base, the number of fins may not be fixed and limited as in conventional heat sinks and may, for example, depend more on geometry and less on construction methodology. Furthermore, by independently manufacturing the base and fins 610, fins 610 may be interchangeable with other fins (not illustrated) that may also be configured to be attached to base.

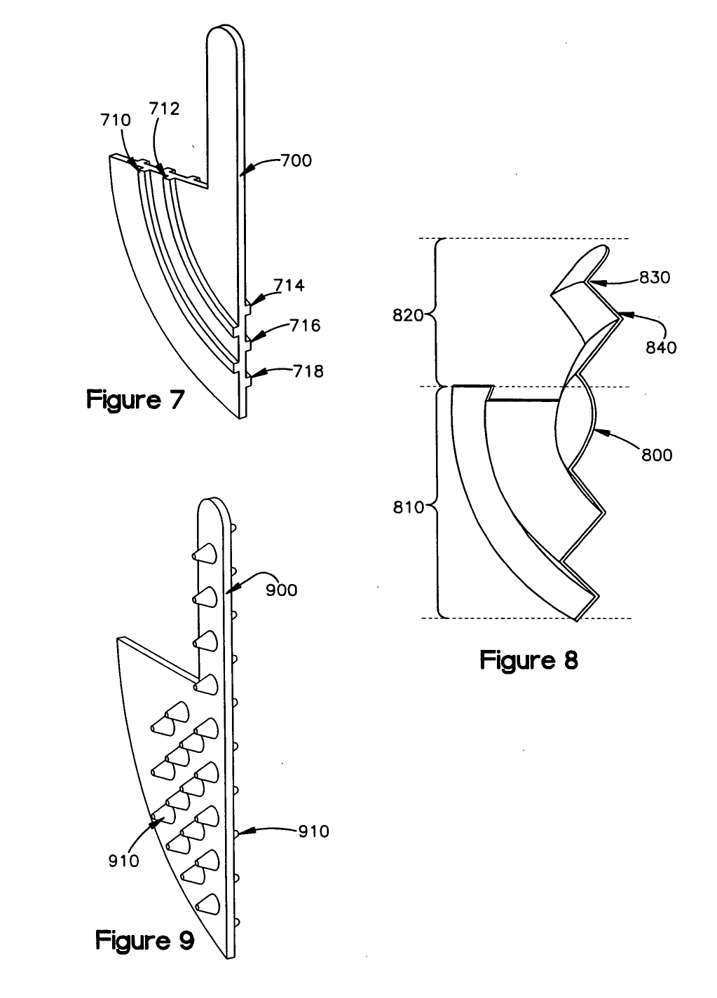

FIG. 7 illustrates an example independently manufactured fin 700. Fin 700 may be employed, for example, in a heat sink device configured to experience a fan-assisted dual air flow. Fin 700 is illustrated having raised features that may be referred to as finlets. For example fin 700 may include finlets 710, 712, 714, 716, and 718. While five finlets having a substantially square cross-section are illustrated, it is to be appreciated that a greater and/or lesser number of finlets having different cross-sections may be employed. Furthermore, while finlets 710 and 712 are illustrated on a first side of fin 700 and finlets 714, 716, and 718 are illustrated on a second side of fin 700, it is to be appreciated that finlets may appear on either and/or both sides of a fin.

The ability of a heat sink device to transfer heat into air depends, among other things, on the surface area of the heat sink exposed to the surrounding air and/or air flows. Thus, a fin may be configured, for example, to facilitate increasing its surface area and thus to improve its heat dissipation performance. Conventionally it has been difficult, if possible at all, to produce fins with finlets due to limitations associated with manufacturing a heat sink base and fins from a single block of material. While finlets are described it is to be appreciated that fin 700 may be configured with other features that facilitate manipulating the surface area of fin 700 and thus affecting its heat transferring properties.

FIG. 8 illustrates another example independently manufactured fin 800. Fin 800 may be employed, for example, in a heat sink device configured to experience a fan-assisted dual air flow. Fin 800 is illustrated as having various surfaces oriented at various angles designed to affect air flow, heat dissipation, and so on. Fin 800 may have a first portion 810 that is configured to facilitate attaching fin 800 to a hyperboloid shaped base and that will experience a first air flow in a heat sink configured to experience a fan-assisted dual air flow. Similarly, fin 800 may have a second portion 820 that will experience a second air flow in a heat sink configured to experience a fan-assisted dual air flow.

Comparing fin 800 to fin 300 (FIG. 3) and fin 700 (FIG. 7) illustrates that fin 800 has a different shape that may have been difficult, if possible at all, to produce using conventional techniques. For example portion 820 may be manufactured with different surfaces oriented at angles 830 and 840 to each other to facilitate directing air in a desired direction inside a heat sink. Additionally, the shape of portion 820 may facilitate increasing the surface area of fin 800 to facilitate improving heat dissipation performance. While various angles and surfaces are illustrated in portion 820 it is to be appreciated that other fins with other surfaces oriented at other angles may be employed.

FIG. 9 illustrates an example independently manufactured fin 900. Fin 900 is configured with raised features 910 designed, for example, to mitigate a boundary layer effect produced by air flowing over fin 900. A boundary layer effect produced when air flows over a substantially flat surface (e.g., fin 300 (FIG. 3)), may result in an insulating effect when the substantially flat surface is being employed for dissipating heat. Since the fins in a heat sink are supposed to dissipate heat, any such insulating effect may reduce the effectiveness of a heat sink. Thus fin 900 is configured with raised features 910 that may disturb an otherwise substantially uniform air flow that may result in a boundary layer effect. While conical sections are illustrated being raised on both surfaces of fin 900, it is to be appreciated that other raised features having other shapes may be employed. Similarly, while the conical raised features are illustrated being distributed substantially uniformly over portions of fin 900, it is to be appreciated that other densities and distributions of such raised features may be employed.

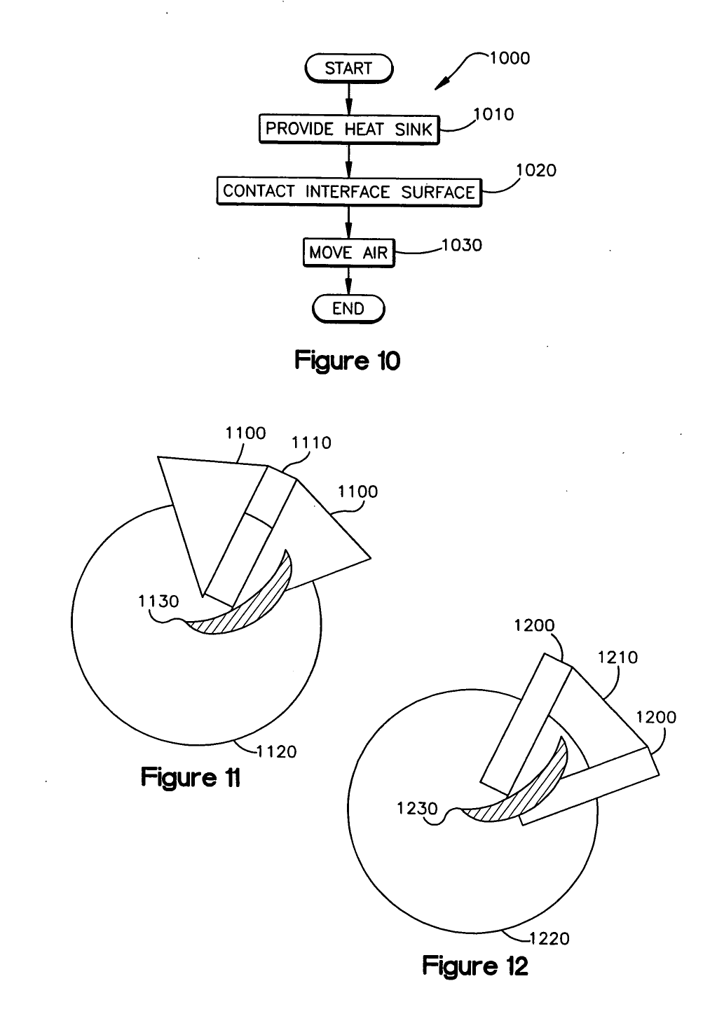

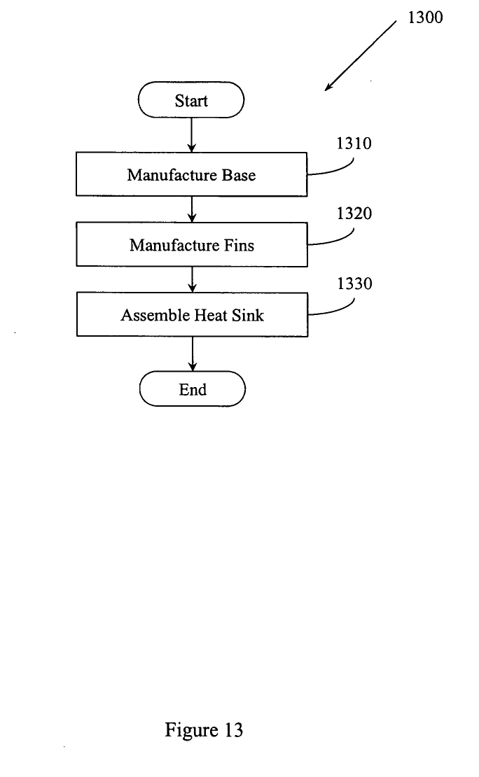

Example methods may be better appreciated with reference to the flow diagrams of FIGS. 10 and 13. While for purposes of simplicity of explanation, the illustrated methodologies are shown and described as a series of blocks, it is to be appreciated that the methodologies are not limited by the order of the blocks, as some blocks can occur in different orders and/or concurrently with other blocks from that shown and described. Moreover, less than all the illustrated blocks may be required to implement an example methodology. Furthermore, additional and/or alternative methodologies can employ additional, not illustrated blocks.

FIG. 10 illustrates an example method 1000 for removing heat from a heat source using a heat sink device configured to experience a fan-assisted dual air flow, where the heat sink device is assembled from independently manufactured parts. Method 1000 may include, at 1010, providing a heat sink apparatus having a fan-assisted dual air flow. The heat sink apparatus may include, for example, a fan and a heat sink that houses the fan. The heat sink may have a base with an interface surface that is configured to contact the heat source. The base may be formed from a first thermally conductive material like copper, aluminum, graphite, carbon, silver, and so on. The heat sink may also include fins that are manufactured separately from the base. The fins may be formed from a second thermally conductive material like copper, aluminum, graphite, carbon, silver, and so on. In one example, the fins may be removably attachable to the base.

Method 1000 may also include, at 1020, contacting the interface surface with the heat source, and, at 1030, causing the fan to move air in the area of the heat sink and the fins. In one example, since the fins are manufactured separately from the base, at least one of the fins may be configured with a feature like a finlet, a raised feature to mitigate boundary layer effects, and so on.

FIG. 11 illustrates a top view of example fins 1100 having an increasing cross-sectional area with respect to radius and a channel 1110 having a constant cross-sectional area with respect to radius. Fins 1100 are the type of fins typically associated with conventional heat sinks manufactured from a single block of material. Fins 1100 may not have an optimal shape for conducting heat on an extended surface. Fins 1100 are illustrated extending outwards from a heat sink cavity 1120 in which a fan having a plurality of fan blades (e.g., fan blade 1130) will rotate. The relationship between the size and/or shape of fin 1100 and channels 1110 may determine, at least in part, a heat transfer property of a heat sink in which the fin 1100 is employed.

FIG. 12 illustrates a top view of example fins 1200 having a constant cross-sectional area with respect to radius and a channel 1210 having an increasing cross-sectional area with respect to radius. Fins 1200 are an example of fins that may be employed when a base and fins are manufactured separately and then assembled into a heat sink having, for example, a fan-assisted dual air flow. Fins 1200 may have a more optimal shape for conducting heat on an extended surface than fins 1100 (FIG. 11). Fins 1200 are illustrated extending outwards from a heat sink cavity 1220 in which a fan having a plurality of fan blades (e.g., fan blade 1230) will rotate. Comparing fins 1100 (FIG. 11) with fins 1200 illustrates that different fins may produce different channels and thus produce different heat transfer properties in heat sinks employing the different fins.

FIG. 13 illustrates an example method 1300 for making a heat sink device from separately manufactured fins and base. At 1310, a base may be manufactured using techniques including, but not limited to, milling, lathing, machining, forging, and so on. The base may be, for example, hyperboloid in shape. The base may be manufactured, for example, from materials like copper, aluminum, and the like. The base may be manufactured to facilitate attaching a fin(s). The base may be manufactured to facilitate producing a fan-assisted dual air flow over a heat sink assembled from the base.

At 1320, a fin may be manufactured using techniques including, but not limited to, milling, pressing, forging, machining, and the like. The fin may have, for example, a variety of structural features like finlets, and so on. The fin may be manufactured, for example, from materials like copper, aluminum, gold, silver, combinations of materials, compounds, and the like. It is to be appreciated that the fin may be manufactured from the same material as the base or from a material different from the base. While a single fin is described, it is to be appreciated that a heat sink device may be configured with a number of fins and thus a number of fins may be manufactured. It is to be appreciated that in various examples, the actions performed at 1310 and 1320 may be performed in different locations, at different times, in different orders, and/or substantially in parallel.

At 1330, the base and the fin(s) may be assembled into a housing. FIG. 4 illustrates an example base 400 having been assembled together with a single fin 410. It is to be appreciated that multiple fins may be assembled together with base 400 to form a housing. The housing may be configured, for example, to house a fan. Thus, in one example, method 1300 may also include (not illustrated), placing a fan into the housing formed from the base and the fin(s). In one example, the fan may be configured to produce a fan-assisted dual flow through the housing formed from the base and the fin(s). The base and the fin(s) may be assembled together using techniques including, but not limited to, welding, soldering, mechanical (e.g., bolting) techniques, male/female attachments, and so on.

While example systems, methods, and so on, have been illustrated by describing examples, and while the examples have been described in considerable detail, it is not the intention of the applicants to restrict or in any way limit the scope of the appended claims to such detail. It is, of course, not possible to describe every conceivable combination of components or methodologies for purposes of describing the systems, methods, and so on, described herein. Additional advantages and modifications will readily appear to those skilled in the art. Therefore, the invention is not limited to the specific details, the representative apparatus, and illustrative examples shown and described. Thus, this application is intended to embrace alterations, modifications, and variations that fall within the scope of the appended claims. Furthermore, the preceding description is not meant to limit the scope of the invention. Rather, the scope of the invention is to be determined by the appended claims and their equivalents.

To the extent that the term “includes” or “including” is employed in the detailed description or the claims, it is intended to be inclusive in a manner similar to the term “comprising” as that term is interpreted when employed as a transitional word in a claim. Furthermore, to the extent that the term “or” is employed in the detailed description or claims (e.g., A or B) it is intended to mean “A or B or both”. When the applicants intend to indicate “only A or B but not both” then the term “only A or B but not both” will be employed. Thus, use of the term “or” herein is the inclusive, and not the exclusive use. See, Bryan A. Garner, A Dictionary of Modern Legal Usage 624 (2d. Ed. 1995).

1. A heat sink apparatus configured to experience a dual air flow, comprising:
a base formed from a thermally conductive material; and
a plurality of fins formed from a thermally conductive material, the plurality of fins being manufactured separately from the base, the plurality of fins being attachable to the base in a configuration that together with the base forms a housing for a fan configured to produce the dual air flow in the heat sink apparatus.

2. The heat sink apparatus of claim 1, the base having a hyperboloid shape.

3. The heat sink apparatus of claim 2, the base being formed from a first thermally conductive material comprising one of, copper, graphite, carbon, gold, silver, aluminum, and compositions thereof.

4. The heat sink apparatus of claim 3, the plurality of fins being formed from a second thermally conductive material comprising one of, copper, graphite, carbon, gold, silver, aluminum, and compositions thereof.

5. The heat sink apparatus of claim 1, the base being formed from a first thermally conductive material comprising one of, copper, graphite, carbon, gold, silver, aluminum, and compositions thereof.

6. The heat sink apparatus of claim 5, the fins being formed from a second thermally conductive material comprising one of, copper, graphite, carbon, gold, silver, aluminum, and compositions thereof.

7. The heat sink apparatus of claim 2, the base being configured with a contacting surface configured to contact a heat source, the contacting surface being form fitted to the heat source.

8. The heat sink apparatus of claim 2, at least one of the plurality of fins being configured with a finlet.

9. The heat sink apparatus of claim 2, at least one of the plurality of fins being configured with a raised feature configured to reduce a boundary layer effect associated with an air flow over the at least one fin.

10. The heat sink apparatus of claim 1, at least one of the plurality of fins being configured with a finlet.

11. The heat sink apparatus of claim 1, at least one of the plurality of fins being configured with a raised feature configured to reduce a boundary layer effect associated with an air flow over the at least one fin.

12. The heat sink apparatus of claim 2, the plurality of fins being attached to the base by one or more of, soldering, welding, and a set of male/female attachments.

13. The heat sink apparatus of claim 2, at least one of the plurality of fins having a constant cross-sectional area with respect to radius.

14. The heat sink apparatus of claim 2, comprising:
a fan configured to produce the dual air flow, the fan being housed in the base.

15. The heat sink apparatus of claim 1, where a first fin in the plurality of fins is configured with one or more features different from a second fin in the plurality of fins.

16. A heat sink apparatus configured to experience a fan-assisted dual air flow, comprising:
a fan configured to produce a dual air flow in the heat sink apparatus; and
a heat sink that houses the fan, the heat sink comprising:
a base having a hyperboloid shape, the base being formed from a conductive material, the base being configured with a contacting surface configured to contact a heat source; and
a plurality of fins formed from a conductive material, the plurality of fins being manufactured separately from the base, at least one of the plurality of fins being configured with one or more of, a finlet, and a raised feature configured to reduce a boundary layer effect associated with an air flow over the at least one fin, the plurality of fins being attachable to the base by one or more of, soldering, welding, and mechanical attachments.

17. A method of removing heat from a heat source, comprising:
providing a heat sink apparatus configured to experience a fan-assisted dual air flow comprising:
a fan;
a heat sink that houses the fan, the heat sink having a base with an interface surface configured to contact the heat source, the base being formed from a thermally conductive material; and
a plurality of fins formed from a thermally conductive material, the fins being manufactured separately from the base and being attachable to the base;
placing the interface surface in contact with the heat source; and
causing the fan to move air in an area of the base and the plurality of fins.

18. The method of claim 17, including configuring at least one of the plurality of fins with a finlet.

19. The method of claim 17, including configuring at least one of the plurality of fins with a raised feature configured to reduce a boundary layer effect associated with an air flow over the at least one fin.

20. (canceled)

21. A heat sink apparatus configured to house a fan configured to produce a dual air flow in the heat sink apparatus, comprising:
a base configured to allow selective attachment of one or more fins; and
one or more fins being interchangeably attachable to the base.

22. The heat sink apparatus of claim 21, the base having a hyperboloid shape.

23. The heat sink apparatus of claim 22, the base being formed using a thermally conductive material comprising one of, copper, graphite, carbon, gold, silver, aluminum, and compositions thereof.

24. The heat sink apparatus of claim 21, at least one of the one or more fins being configured with a raised feature configured to increase a surface area of the at least one fin.

25. The heat sink apparatus of claim 21, at least one of the one or more fins being configured with a raised feature configured to reduce a boundary layer effect associated with an air flow over the at least one fin.

26. The heat sink apparatus of claim 21, the one or more fins being manufactured as a separate component from the base.

27. The heat sink apparatus of claim 21, the base being formed from a thermally conductive material that is different from at least one of the one or more fins.

28. A system for removing heat from a heat source using a dual air flow and independently manufactured components, comprising:
means for housing a fan configured to produce the dual air flow, where the means for housing are configured to conduct heat away from the heat source; and
means for dissipating heat by convection into the dual air flow from the means for housing the fan.

29-31. (canceled)
